(19) United States
(12) Patent Application Publication
(10) Pub. No.: US 2019/0006574 A1
(43) Pub. Date: Jan. 3, 2019

(54) A PIEZOELECTRIC THIN FILM ELEMENT

(71) Applicant: XAAR TECHNOLOGY LIMITED, Cambridgeshire (GB)

(72) Inventors: Peter Mardilovich, Cambridgeshire (GB); Susan Trolier-Mckinstry, University Park, PA (US); Subramanian Sivaramakrishnan, Cambridgeshire (GB)

(73) Assignee: XAAR TECHNOLOGY LIMITED, Cambridgeshire (GB)

(21) Appl. No.: 15/735,905

(22) PCT Filed: Jun. 10, 2016
(86) PCT No.: PCT/GB2016/051741

§ 371 Date: Dec. 12, 2017

Related U.S. Application Data
(60) Provisional application No. 62/175,056, filed on Jun. 12, 2015.

(30) Foreign Application Priority Data
Dec. 24, 2015 (GB) 1522871.1

(51) Int. Cl. H01L 41/083; H01L 41/047; H01L 41/09; H01L 41/277; H01L 41/293; B41J 2/14

(52) U.S. Cl. CPC H01L 41/0838; H01L 41/0472; H01L 41/0831; B41J 2002/14266; H01L 41/277; H01L 41/293; B41J 2/14233; H01L 41/0973

(57) ABSTRACT

There is disclosed a piezoelectric thin film element comprising a first electrode, a second electrode and one or more piezoelectric thin films there between characterised in that the thin film element has at least two of:
an electrode arrangement in which electrodes are arranged with the one or more piezoelectric thin films so that an electric field applied to a piezoelectric thin film or a portion of a piezoelectric thin film adjacent to the first electrode is lower than an electric field applied to a piezoelectric thin film or a portion of a piezoelectric thin film further from the first electrode when the piezoelectric thin film element actuated;
a piezoelectric thin film adjacent to the first electrode in which a layer of the piezoelectric thin film near to the first electrode has a piezoelectric displacement constant which is lower than that of a layer of the piezoelectric thin film further from the first electrode; and
a piezoelectric thin film adjacent to the first electrode in which a layer of the piezoelectric thin film near to the first electrode has an elastic modulus which is lower than that of a layer of the piezoelectric thin film further from the first electrode.

The present invention is generally concerned with a piezoelectric thin film element suitable for use in actuators, sensors, energy harvesting devices and multilayer capacitors as well as a method of manufacturing the element.

It is particularly, although not exclusively, concerned with a piezoelectric thin film element suitable for use as an actuator for a printhead in an inkjet printer, as well as with actuators including the element, printheads including the actuator and inkjet printers including the printheads.

A typical piezoelectric thin film element suitable for use as an actuator for a printhead in an inkjet printer comprises a piezoelectric layer with appropriate metallization. For instance, the actuator may comprise a metal or metal oxide bottom electrode, a metal top electrode and a piezoelectric thin film interposed between the top and bottom electrodes.

The piezoelectric thin film element is used with a diaphragm or membrane which may be provided between the bottom electrode and the substrate. The substrate is configured so that the diaphragm and the substrate together define a pressure chamber from which ink can be dispensed through one or more nozzles formed in or with the substrate when the piezoelectric thin film element is driven by an applied voltage.

The piezoelectric thin film may comprise a single layer or a laminate formed from a plurality of thin film layers of a piezoelectric material.

The thin film may, in particular, be formed by a variety of techniques including sputtering, physical vapour deposition (PVD), chemical vapour deposition (CVD), pulsed laser deposition (PLD) and atomic layer deposition (ALD)—but it is conveniently formed by a chemical solution deposition process such as a sol-gel process.

A sol-gel process is described in US patent application 2003/0076007 A1 (incorporated by reference herein).

In a chemical solution deposition method, for example in a chemical solution deposition process, for example a sol-gel process, a sol-gel solution is applied to the bottom electrode formed on the substrate, dried and then pyrolysed to form a first precursor layer. The precursor layer is annealed by heating to form a first piezoelectric thin film layer. The sol-gel solution is then applied to the first layer, dried and pyrolysed to form a second precursor layer. The second precursor layer is annealed by heating to form a second piezoelectric thin film layer.

These latter steps are repeated so as to build up a laminate of piezoelectric thin film layers of desired thickness and then a top electrode is formed on the thin film (for example, by sputtering, gold or iridium).

The performance of a piezoelectric thin film element depends on a complex interplay of piezoelectric, electrical and mechanical properties of the element which can be difficult to balance.

In general, it is desired that the element poles easily and shows a relatively large displacement response at conveniently applied electrical fields and has good electrical properties such as low current leakage and high dielectric breakdown field. Whilst the performance of the piezoelectric thin film element is important, it is also important that the piezoelectric actuator shows good reliability over a large number of applications (cycles) of the electric field.

One problem for reliability in piezoelectric actuators is the tendency of the structure to crack or delaminate due to electrical excitation. In one arrangement, this may cause a bottom electrode to delaminate from the diaphragm or the piezoelectric thin film contacting the bottom electrode to crack or to delaminate from the bottom electrode.

This tendency is a result of large lateral stresses which arise in the piezoelectric film and the bottom electrode layer (including so called “interface stresses”) as the piezoelectric element displaces, with respect to the substrate, when it is driven. The stresses can also be compounded by film deposition stresses, or poor adhesion of one or more of the layers in the stack.

The stress performance of piezoelectric actuators has been considered in the prior art.

EP 1372199 A1, for example, discloses a piezoelectric actuator comprising a (bimorph-type) piezoelectric device having piezoelectric films and electrode films which are alternately laminated. The film layer contacting the bottom electrode is thicker than the film layer contacting the adjacent electrode so as to provide high aspect ratio and good rigidity as well as raised bend efficiency. The focus of this prior art is to improve the performance efficiency rather than the stresses in the films pertaining to reliability.

US 2008/0024563 A1 discloses a piezoelectric film in which a first piezoelectric layer and a third piezoelectric layer have a piezoelectric constant d₃₁ which is smaller than that of a second piezoelectric layer. The arrangement is to reduce an internal stress generated at an interface between electrode layers 13 and 15 provided on the first and third piezoelectric layers.

US 2007/0090728 A1 discloses a piezoelectric substance having a multilayer structure consisting of single crystal layers or uniaxial crystal layers which are doped wherein the first layer has a first crystal phase and the second layer has a second crystal phase with a boundary layer therebetween, wherein the crystal structure gradually changes in the thickness direction of the layer.

This prior art tends to focus on device performance without commenting extensively on reliability.

In contrast, the present invention generally aims to provide a piezoelectric thin film element in which stress has been engineered to improve reliability at conveniently applied electrical fields.

In particular, the present invention aims to provide a piezoelectric thin film element of improved reliability whilst maintaining good performance.

Accordingly, in a first aspect the present invention provides a piezoelectric thin film element comprising a first electrode, a second electrode and one or more piezoelectric thin films characterised in that the thin film element has at least two of:

an electrode arrangement in which electrodes are arranged with the one or more piezoelectric thin films so that an electric field applied to a piezoelectric thin film or a portion of a piezoelectric thin film adjacent to the first electrode is lower than an electric field applied to a piezoelectric thin film or a portion of a piezoelectric thin film further from the first electrode when the piezoelectric thin film element is actuated;

a piezoelectric thin film adjacent to the first electrode in which a layer of the piezoelectric thin film near to the first electrode has a piezoelectric displacement constant which is lower than that of a layer of the piezoelectric thin film further from the first electrode; and

a piezoelectric thin film adjacent to the first electrode in which a layer of the piezoelectric thin film near to the first electrode has an elastic modulus which is lower than that of a layer of the piezoelectric thin film further from the first electrode.

As used herein, the term “layer” refers to a layer in the piezoelectric thin film which is formed by any of the methods known to the art and, in particular, the above-mentioned methods.

It will be understood, therefore, that the piezoelectric thin film can comprise not just discrete layers in which the piezoelectric displacement constant and/or elastic modulus are the same in a particular layer in the thickness direction of the element but also thin film layers in which the piezoelectric displacement constant and/or elastic modulus continuously vary in the thickness direction of the element.

Further, the term “near to” as applied to a piezoelectric thin film layer refers to a layer in the piezoelectric thin film which is within a distance of 1 nm and 200 nm, for example 1 and 100nm, 60 nm, 15 nm, or 5 nm of the first electrode.

The piezoelectric thin film or a portion of a piezoelectric thin film further from the first electrode may in embodiments be adjacent to the second electrode.

Actuation may be implemented by driving the piezoelectric thin film element with one or more predetermined voltages.

In one embodiment, the piezoelectric thin film element comprises the aforementioned electrode arrangement and a piezoelectric thin film adjacent to the first electrode in which a layer of the piezoelectric thin film near to the first electrode has a piezoelectric displacement constant which is lower than that of a layer of the piezoelectric thin film further from the first electrode.

In another embodiment, the piezoelectric thin film element comprises the aforementioned electrode arrangement and a piezoelectric thin film adjacent to the first electrode in which a layer of the piezoelectric thin film near to the first electrode has an elastic modulus which is lower than that of a layer of the piezoelectric thin film further from the first electrode.

In a preferred embodiment, the piezoelectric element comprises the aforementioned electrode arrangement and a piezoelectric thin film adjacent to the first electrode in which a layer of the piezoelectric thin film near to the first electrode has a piezoelectric displacement constant and an elastic modulus which are lower than those of a layer of the piezoelectric thin film further from the first electrode.

The piezoelectric thin film element may, in particular, comprise an electrode arrangement in which the first electrode, the second electrode and one or more additional electrodes are arranged with a plurality of piezoelectric thin films so that the electrodes interpose and alternate with the thin films.

In that case, the piezoelectric thin film element may also comprise one or more piezoelectric thin films which are adjacent to an additional electrode in which a layer of the piezoelectric thin film near to that electrode has a piezoelectric displacement constant and/or an elastic modulus which are lower than those of a layer of the piezoelectric thin film further from the additional electrode.

The piezoelectric thin film element may, in particular, comprise an electrode arrangement in which three piezoelectric thin films are alternately interposed between the first electrode, the second electrode and two additional electrodes.

In one such arrangement, the piezoelectric thin films may have different thickness so that the thickness of the piezoelectric thin film adjacent the first electrode is greater than that of a piezoelectric thin film adjacent the neighbouring electrode and so on—and the first and second electrodes are separately addressed, with respective additional electrodes, by two predetermined voltages derived from independent sources.

In this arrangement, the polarisation of the piezoelectric thin film adjacent the first electrode and of the piezoelectric thin film adjacent the second electrode may be in the same direction whilst the polarisation of the intervening piezoelectric thin film is in the opposite direction.

Such an arrangement provides that the electric field applied to the piezoelectric thin film adjacent the first electrode is lower than that applied to the piezoelectric thin film adjacent the neighbouring electrode (and so on).

In another such arrangement, the three piezoelectric thin films have the same thicknesses and the first electrode is addressed together with a respective additional electrode by a first predetermined voltage and the second electrode and a respective additional electrode are separately addressed by respective predetermined voltages from sources which are independent to each other and the source of the first predetermined voltage.

In this arrangement, the polarisation of the piezoelectric thin film adjacent the first electrode and the polarisation of the piezoelectric thin film adjacent the second electrode are in the same direction whilst the polarisation of the intervening piezoelectric thin film is in the opposite direction.

If the additional electrode respective to the second electrode is separately addressed by a voltage lower than that addressing the second electrode, such an arrangement also provides that the electric field applied to the thin film adjacent the first electrode is lower than the electric field applied to the thin film adjacent the neighbouring electrode.

In still another such arrangement, the three thin piezoelectric films have the same thicknesses and the first electrode, the second electrode and each of the additional electrodes are separately addressed by a respective predetermined voltage from independent sources.

In this arrangement, the polarisation of the piezoelectric material of the thin film adjacent the first electrode and the polarisation of the thin film adjacent the second electrode are in the same direction whilst the polarisation of the piezoelectric material of the intervening thin film is in the opposite direction.

If the respective predetermined voltages are suitably chosen, the electric field applied to the thin film adjacent the first electrode is lower than the electric field applied to the adjacent thin film which is in turn lower than the electric field applied to the thin film contacting the second electrode.

Of course, the piezoelectric thin film element may also comprise more than three thin films in which one or more of these arrangements of electrodes and thin films are repeated as many times as desired (for example, two or three times) in the thickness direction of the element.

In any case, however, the thin film adjacent the first electrode related to each single arrangement will experience an electric field which is lower than that applied to the adjacent thin film.

As used herein, the expression “adjacent” as applied to piezoelectric thin films does not necessarily require that the thin films are contacting an electrode. Those skilled in the art will appreciate that the piezoelectric thin films may not contact the electrodes but could instead be a seed layer or a buffer layer provided on the electrodes.

The expression “neighbouring” as applied to additional electrodes means nearest as compared to other additional electrodes.

In another electrode arrangement, the piezoelectric thin film element may have only a single piezoelectric thin film in the form of a laminate of piezoelectric thin film layers and a first electrode and a second electrode.

The first electrode and the second electrode may be arranged on a single surface of a piezoelectric thin film or on opposing sides of the piezoelectric element.

When they are arranged on the same surface of a piezoelectric thin film, the first electrode and the second electrode may be interdigitated with each other.

In that case, the first electrode and the second electrode are preferably interdigitated to a large extent and with the spacing between respective digits large as compared to the piezoelectric film thickness and the electrode widths comparable to the piezoelectric film thickness, and across substantially the whole of the surface of the thin film.

And the polarisation of the piezoelectric thin film is such that it is parallel to the piezoelectric thin film layers and in opposite directions between adjacent pairs of digits of the electrodes.

In all these electrode arrangements, the piezoelectric thin film or the piezoelectric thin film adjacent to the first electrode may have a layer near to the first electrode which has a piezoelectric displacement constant or the elastic modulus or both, lower than those of a layer of the piezoelectric thin film further from the first electrode.

It will be understood that the piezoelectric thin film adjacent the first electrode will comprise a plurality of piezoelectric thin film layers which together may define a gradient in piezoelectric displacement constant or elastic modulus or both across at least a part of the thin film in its thickness direction.

As used herein, a reference to the thickness direction of a thin film is a reference to the direction away from the first electrode.

The thin film layer near to the first electrode may comprise a different piezoelectric material to that of the thin film layer further from the first electrode.

It is preferred, however, that it comprise essentially the same piezoelectric material but has at least one of different porosity, different texture, different grain size and different composition of constituent elements.

The piezoelectric thin film may be formed by employing different film forming methods—but it is preferred that it is formed by a single film forming method employing different targets or a different processing condition for forming the thin film layer near to the first electrode as compared to forming the thin film layer or layers further from the first electrode.

The different processing condition may, for example, provide that the extent of a crystal orientation in the thin film layer near to the first electrode is different or substantially less than the extent of crystal orientation in the thin film layer further from the first electrode.

The thin film may, for example, be formed by a sputtering method or by a vapour deposition method or by an atomic layer deposition method and the different processing condition may include one or more of lower deposition temperature, different deposition rate, different deposition angle and different partial pressure of oxygen.

The thin film may, in particular, be formed by a sol-gel method and the processing condition may include sub-optimal heating for pyrolysis of the sol-gel layer and/or sub-optimal heating for crystallisation of the pyrolysed layer. The sub-optimal heating may employ a lower or higher temperature and/or be of shorter or longer duration than that which is accepted as desirable for the piezoelectric material of the thin film layer.

Such methods may or may not be employed in forming similar or different piezoelectric thin films adjacent to an additional electrode in these electrode arrangements.

In all the electrode arrangements and combinations of the same, the piezoelectric thin film or the piezoelectric thin film adjacent to the respective first electrode may alternatively have a piezoelectric thin film layer near to the first electrode which has an elastic modulus or a displacement constant or both lower than those of a piezoelectric thin film layer further from the first electrode.

In this embodiment, the thin film layer near to the first electrode will generally develop lower stress than the film layer further from the first electrode for a given applied electric field.

It will be understood that the piezoelectric thin film adjacent the first electrode will comprise a plurality of piezoelectric thin film layers which together may define a gradient in elastic modulus or a piezoelectric strain constant or both, across at least a part of the thin film in its thickness direction.

The piezoelectric thin film layer near the first electrode may comprise a different material to that of the piezoelectric thin film layer further from the first electrode.

It is preferred, however, that it comprise essentially the same piezoelectric material but has different porosity and/or different composition of constituent elements.

The piezoelectric thin film may be formed by employing different film forming methods—but it is preferred that it is formed by a single film forming method employing different targets or a different processing condition for forming the thin film layer near to the first electrode as compared to forming the thin film layer further from the first electrode.

The different processing condition may relate to one or more parameters which are deliberately chosen to be sub-optimal to those accepted as most desirable in the art.

The different processing condition may, for example, provide that the extent of a crystal orientation in the thin film layer near to the first electrode is different or substantially less than the crystal orientation in the thin film layer further from the first electrode.

The thin film may, for example, be formed from the methods mentioned above provided that the method results in the piezoelectric thin film layer near to the first electrode having an elastic modulus and/or piezoelectric constant lower than that of the thin film layer further from the first electrode.

The piezoelectric thin film adjacent the first electrode may include one or more piezoelectric thin film layers which are doped by at least one of a donor dopant and an acceptor dopant.

In that case, the piezoelectric thin film is conveniently formed by employing differently doped precursor materials (for example, as different targets) in the aforementioned methods.

The piezoelectric thin film adjacent the first electrode may, in particular, comprise a plurality of doped, piezoelectric thin film layers which provide a gradient in dopant concentration across at least a part of the thin film in its thickness direction.

As elastic modulus and piezoelectric displacement constant can be affected in opposite direction by doping, it will be understood that this will be taken into account when choosing the dopant and the doping profile in order to obtain a piezoelectric element characterised in that the stress at the interface between the first electrode and the adjacent piezoelectric layer will be reduced. The same approach may also be applied to the piezoelectric layers adjacent to additional electrodes.

The piezoelectric thin film may, however, include one or more piezoelectric thin film layers which are undoped.

The donor dopant in the piezoelectric thin film layer near to the first electrode may be different to that of the piezoelectric thin film layer or layers further from the first electrode. Preferably, however, the donor dopant is the same dopant for all the doped thin film layers.

In another doping arrangement, the piezoelectric thin film comprises thin film layers which are singly doped by an acceptor dopant.

The acceptor dopant in the piezoelectric thin film layer near to the first electrode may be different from or the same as that of the piezoelectric thin film layer or layers further from the first electrode.

The piezoelectric thin film may include piezoelectric thin film layers which are undoped.

In another doping arrangement, the doped thin film layers include a plurality of piezoelectric thin film layers which are doped by an acceptor dopant and define a gradient in acceptor dopant concentration in the thickness direction of the film, and a plurality of adjacent piezoelectric thin film layers which are doped by a donor dopant and define a gradient in dopant concentration in the thickness direction of the film.

This doping arrangement may be considered as combining the aforementioned doping arrangements in the piezoelectric thin film.

Of course, a piezoelectric thin film adjacent to an additional electrode may also comprise a plurality of piezoelectric thin film layers wherein the thin film is formed (and in particular, doped) in a different or the same way as the piezoelectric thin film adjacent the first electrode.

The doping could be applied or not in conjunction with non-ideal process condition in order to provide a piezoelectric element characterised in that the piezoelectric layer in contact with the first electrode has a modulus, a displacement constant or both lower than those of the piezoelectric layers further from the first electrode. The modulus or the displacement constant or both, may or may not define a gradient in the piezoelectric element thickness direction.

In all the electrode arrangements, the piezoelectric thin film adjacent to the first electrode may have a piezoelectric thin film layer near to the first electrode which has a piezoelectric displacement constant and elastic modulus lower than those of a piezoelectric thin film layer further from the first electrode.

In this embodiment, the thin film layer near to the first electrode may be chosen to displace further or less than the film layer further from the first electrode for a given applied electric field.

It will be understood that the piezoelectric thin film adjacent the first electrode will comprise a plurality of piezoelectric thin film layers which together may define a gradient in each of piezoelectric displacement constant and elastic modulus across at least a part of the thin film in its thickness direction.

The piezoelectric thin film layer near to the first electrode may comprise the same or a different material to that of the piezoelectric thin film layer further from the first electrode as described above.

The piezoelectric thin film adjacent the first electrode may be formed by employing different film forming methods or a single film forming method in the same way as described above.

It is preferred, however, that the piezoelectric thin film adjacent the first electrode comprise thin film layers of essentially the same piezoelectric material but of different porosity and/or different composition of constituent elements.

The piezoelectric thin film adjacent the first electrode may, in particular, be doped in the same way as described above.

Of course, a piezoelectric thin film adjacent to an additional electrode may also comprise a plurality of piezoelectric thin film layers wherein the thin film is formed (and, in particular, doped) in a different or the same way as the piezoelectric thin film adjacent the first electrode.

Such methods may or may not be employed in forming similar or different piezoelectric thin films adjacent to an additional electrode in these electrode arrangements or combinations of the same.

In all of the foregoing embodiments, the piezoelectric thin film element may have at least one end surface which is beveled or filleted.

The piezoelectric thin film element may, in particular, have one, two, three or four end surfaces which are beveled or filleted and forms one or more angles with the diaphragm between 45° and 75°, for example, 65°, 70°, 60°, or 50°, to the plane of the substrate.

Suitable piezoelectric materials, dopants and dopant precursor materials for the present invention will be apparent to those skilled in the art.

Preferred piezoelectric materials include PZT and lead-free alternatives including, for example, potassium sodium niobate (KNN) and those of binary or tertiary composition known in the art as BNT-BT, BKT-BNT, BKT-BZT, BKT-BNT-BZT and BKT-BNT-BT.

Suitable donor dopants include Fe³⁺, Ni²⁺, La³⁺, Nb⁵⁺, Ta⁵⁺, V⁵⁺, U⁵⁺, W⁶⁺ and divalent or trivalent ions of the alkaline earth and rare earth elements. Suitable acceptor dopants include Na⁺, K⁺, Cs⁺ and Rb⁺ as well as Cr³⁺, Li⁺, Co²⁺, Ni²⁺, Cu²⁺, Cu⁺, Y³⁺ and Ti⁴⁺, Zr⁴⁺ and Sn⁴⁺.

The dopant concentration may be characterised by being present in a concentration up to 20 atom % of the type of sites they replace.

In a second aspect, the present invention comprises a method for manufacturing a piezoelectric thin film element having a first electrode, a second electrode and one or more piezoelectric thin films between the electrodes, characterised in that the method comprises at least two of:

forming a piezoelectric thin film adjacent to the first electrode so that a layer of the piezoelectric thin film near to the first electrode has a piezoelectric displacement constant which is lower than that of a layer of a piezoelectric thin film further from the first electrode;

forming a piezoelectric thin film adjacent to the first electrode so that a layer of the piezoelectric thin film near to the first electrode has an elastic modulus which is lower than that of a layer of the piezoelectric thin film further from the first electrode; and

arranging electrodes with the one or more piezoelectric thin films so that an electric field applied to a piezoelectric thin film or a portion of a piezoelectric thin film adjacent to the first electrode is lower than an electric field applied to a piezoelectric thin film or a portion of the piezoelectric thin film adjacent to the second electrode when the piezoelectric thin film element is driven by one or more predetermined voltages.

In one embodiment, the method comprises forming a piezoelectric thin film adjacent to the first electrode in which a layer of the piezoelectric thin film near to the first electrode has a piezoelectric displacement constant which is lower than that of a layer of the piezoelectric thin film further from the first electrode and arranging electrodes in the aforementioned manner.

In another embodiment, the method comprises forming a piezoelectric thin film adjacent to the first electrode so that a layer of the piezoelectric thin film near to the first electrode has an elastic modulus which is lower than that of a layer of the piezoelectric thin film further from the first electrode and arranging electrodes in the aforementioned manner.

In a preferred embodiment, the method comprises forming a piezoelectric thin film adjacent to the first electrode so that a layer of the piezoelectric thin film near to the first electrode has a piezoelectric displacement constant and an elastic modulus which are lower than those of a layer of the piezoelectric thin film further from the first electrode and arranging electrodes in the aforementioned manner.

The method may, in particular, comprise arranging the first and second electrodes with one or more additional electrodes and a plurality of piezoelectric thin films.

The method may, in particular, comprise arranging the first electrode, the second electrode and one or more additional electrodes so that they interpose and alternate with a plurality of piezoelectric thin films.

In that case, the method may comprise forming a piezoelectric thin film adjacent to an additional electrode so that a layer of the piezoelectric thin film has piezoelectric displacement constant and/or an elastic modulus which are lower than those of a layer of the piezoelectric thin film further from the additional electrode.

The method may, in particular, comprise arranging the first electrode, the second electrode and two additional electrodes so that they interpose and alternate with three piezoelectric thin films.

The method may comprise forming these thin films with different thicknesses from one another and arranging the electrodes therewith so that the thin film adjacent the first electrode has thickness greater than the thin film adjacent a neighbouring electrode (which may have thickness greater than that of the thin film contacting the neighbouring electrode and so on) and the first and second electrodes are separately addressed with a respective additional electrode by two predetermined voltages derived from independent sources.

In particular, the method may also comprise poling the piezoelectric thin film adjacent the first electrode, the thin film adjacent the second electrode and the intervening thin film so that the polarisation of the intervening thin film is in a different direction, preferably the opposite direction, to the polarisation of each of the other thin films.

Of course, the method may comprise repeatedly arranging these electrodes with thin films of differing thicknesses in like manner and as many times as desired (for example, two or three times).

In any case, however, the thin film adjacent the first electrode will have thickness greater than that of the thin film adjacent a neighbouring electrode so that the electric field applied to the thin film adjacent the first electrode will be lower than that applied to the thin film adjacent the neighbouring electrode (and so on).

The method may alternatively comprise forming these thin films so that they have similar thicknesses and arranging the electrodes therewith so the first electrode is addressed together with a respective additional electrode by a first predetermined voltage and the second electrode and a respective additional electrode are separately addressed by two predetermined voltages from sources which are independent from each other and the source of the first predetermined voltage.

In particular, the method may also comprise poling the thin film adjacent the first electrode, the intervening thin film and the thin film adjacent the second electrode so that the polarisation in the intervening thin film is opposite in direction to that in each of the thin film adjacent the first electrode and the thin film adjacent the second electrode.

Of course, the method may comprise repeatedly arranging these electrodes with thin films of similar thicknesses in like manner and as many times as desired (for example, two or three times) in the thickness direction of the thin film element.

The method may, however, comprise forming these thin films so that they have similar thicknesses and arranging the electrodes therewith so that the first electrode, the second electrode and each of the additional electrodes are separately addressed by a respective predetermined voltage from independent sources.

In particular, the method may also comprise poling the thin film adjacent the first electrode, the intervening thin film and the thin film adjacent the second electrode so that the polarisation in the intervening thin film is in a different direction, preferably is in an opposite in direction to that in each of the thin film adjacent the first electrode and the thin film adjacent the second electrode.

Of course, the method may comprise repeatedly arranging these electrodes with thin films of differing thicknesses in like manner and as many times as desired (for example, two or three times).

In another embodiment, the method comprises arranging the first electrode and the second electrode with a single piezoelectric thin film in the form of a laminate of piezoelectric thin film layers.

The method may, in particular, comprise arranging the first electrode and the second electrode on the same surface of a piezoelectric thin film or on opposing sides of the piezoelectric element.

When the method comprises arranging the first electrode and the second electrode on the same surface of a piezoelectric thin film, it may provide that the first and second electrodes are interdigitated with each other.

Preferably, the method provides that the first electrode and the second electrode are interdigitated to a large extent and with carefully chosen spacing between respective digits and across substantially the whole of the surface of the thin film.

In this embodiment, the method may also comprise poling the thin film so that the polarisation of the piezoelectric thin film is such that it is parallel to the piezoelectric thin film layers and in different, preferably opposite directions between adjacent pairs of digits of the electrodes.

However the electrodes are arranged, the method may comprise forming a piezoelectric thin film adjacent to the first electrode so that it has a layer near to the first electrode which has a piezoelectric displacement constant lower than that of a layer further from the first electrode.

In this embodiment, the method provides that the thin film layer adjacent to the first electrode will displace less than the thin film layer further from the first electrode for a given applied electric field.

The method may comprise forming a plurality of piezoelectric thin film layers which together define a gradient in piezoelectric displacement constant and/or elastic modulus across at least a part of the thin film in its thickness direction.

The method may comprise forming the thin film layer adjacent to the first electrode and the thin film layer further from the first electrode from a different piezoelectric material.

It may alternatively comprise forming the thin film layer adjacent to the first electrode and the thin film layer further from the first electrode from essentially the same piezoelectric material but with at least one of different porosity, different texture, different grain size and different composition of constituent elements.

The method may comprise forming the thin film layer near to the first electrode and the thin film layer further from the first electrode by one or more different film forming methods (such as those mentioned above).

Preferably, however, it comprises forming the thin film by a single film forming method. It may, in particular, comprise forming the thin film layer near to the first electrode and the thin film layer further from the first electrode using a different target or a different processing condition.

The different processing condition may relate to one or more parameters which are deliberately chosen to be sub-optimal to those accepted as most desirable in the art. The different processing condition may, for example, provide a method forming a crystal orientation of lower extent in the thin film layer near to the first electrode as compared to the thin film layer further from the electrode.

The method may comprise forming the thin film layer near to the first electrode with a lower crystal orientation providing that the thin film layer contacting the first electrode comprises the same material as that of the adjacent thin film layer but deposited by a different process than that of the adjacent thin film layer.

In this embodiment, the method may comprise forming the piezoelectric thin film by a sputtering or by vapour deposition or by atomic layer deposition and the different processing condition may include one or more of different deposition temperature, different deposition rate, different deposition angle and different partial pressure of oxygen from those regarded as preferable in the art.

Alternatively, the method may comprise forming the piezoelectric thin film by chemical solution deposition such as a sol-gel process and the different processing condition may include sub-optimal heating for pyrolysis of the sol-gel layer and/or sub-optimal heating for crystallisation of the pyrolysed layer. The sub-optimal heating may, in particular, employ a lower or higher temperature and/or be of shorter or longer duration than that which is accepted as desirable for the piezoelectric material of the thin film layer.

The method may also comprise forming similar or different piezoelectric thin films adjacent to one or more additional electrodes.

However the electrodes are arranged, the method may comprise forming a piezoelectric thin film adjacent to the first electrode so that a piezoelectric thin film layer near to the first electrode has an elastic modulus and/or a piezoelectric displacement constant lower than those of a piezoelectric thin film layer further from the first electrode.

In this embodiment, the method provides that the thin film layer near to the first electrode will generally develop lower stress than the thin film layer further from the first electrode for a given applied electric field.

The method may comprise forming the piezoelectric film adjacent the first electrode so that a plurality of piezoelectric thin film layers together define a gradient in elastic modulus and/or piezoelectric strain constant across at least a part of the thin film in its thickness direction.

The method may comprise forming the thin film layer adjacent to the first electrode and the thin film layer further from the first electrode from different piezoelectric materials.

It may alternatively comprise forming the thin film layer adjacent to the first electrode and the thin film layer further from the first electrode from essentially the same piezoelectric material but with a different porosity and/or a different texture and/or a different grain size and/or a different composition of constituent elements.

The method may comprise forming the thin film layer near to the first electrode and the thin film layer further from the first electrode by one or more different film forming methods (such as those mentioned above).

Preferably, however, it comprises forming the thin film by a single film forming method. It may, in particular, comprise forming the thin film layer near to the first electrode and the thin film layer further from the first electrode using a different target or a different processing condition.

The different processing condition may relate to one or more parameters which are deliberately chosen to be sub-optimal to those accepted as most desirable in the art. The different processing condition may, for example, provide a method of forming a crystal orientation of lesser extent in the thin film layer near the electrode as compared to the thin film layer further from the electrode.

The method may comprise forming the piezoelectric thin film as described above provided that a piezoelectric thin film layer near to the first electrode has an elastic modulus and/or a piezoelectric displacement constant lower than those of the thin film layer further from the first electrode.

The method may, in particular, comprise forming a piezoelectric thin film adjacent the first electrode which is doped by at least one of a donor dopant and an acceptor dopant.

In that case, the method comprises forming the piezoelectric thin film from differently doped precursor materials (for example, provided as different targets).

The method may, in particular, comprise forming the piezoelectric thin film adjacent the first electrode so that a plurality of doped, piezoelectric thin film layers provide a gradient in dopant concentration across at least a part of the thin film in its thickness direction.

The method may, however, comprise forming an undoped piezoelectric thin film layer.

The method may provide that the donor dopant in the piezoelectric thin film layer near the first electrode is different to that of the piezoelectric thin film layer further from the first electrode. Preferably, the method provides that the donor dopant is the same for all the doped thin film layers.

The method may comprise forming the piezoelectric thin film adjacent the first electrode so that a plurality of thin film layers are singly doped by an acceptor dopant.

In that case, the method may provide that one or more thin film layers are undoped.

The method may comprise forming the piezoelectric thin film or the piezoelectric thin film adjacent the first electrode so that a plurality of thin film layers are doped by an acceptor dopant and define a gradient in acceptor dopant concentration in the thickness direction of the film and a plurality of adjacent piezoelectric thin film layers which are doped by a donor dopant and define a gradient in dopant concentration in the thickness direction of the film. The piezoelectric film may also comprise undoped piezoelectric film layers.

Of course, the method may also comprise forming a thin film adjacent to an additional electrode which may also comprise a plurality of piezoelectric thin film layers in which the thin film layer contacting the additional electrode is doped in the same way as the thin film contacting the first electrode.

However the electrodes are arranged, the method may comprise forming a piezoelectric thin film adjacent to the first electrode so that a piezoelectric thin film layer near to the first electrode has a piezoelectric displacement constant and an elastic modulus lower than those of a piezoelectric thin film layer further from the electrode.

In this embodiment, the method provides that the thin film layer near to the first electrode can be chosen to develop lower stress than the film layer further from the first electrode for a given applied electric field.

The method may also comprise forming the piezoelectric thin film adjacent the first electrode having a plurality of piezoelectric thin film layers which together define a gradient in each of piezoelectric displacement constant and elastic modulus across at least a part of the thin film in its thickness direction.

The method may comprise forming the thin film layer near to the first electrode and the thin film layer further from the first electrode by one or more different film forming methods (such as those mentioned above).

It may alternatively comprise forming the thin film layer adjacent to the first electrode and the thin film layer further from the first electrode from essentially the same piezoelectric material but with a different porosity and or different texture and/or different grain size and/or a different composition of constituent elements.

The method may, in particular, comprise forming the piezoelectric thin film adjacent the first electrode so that it is doped in the same way as described above.

The method may also comprise forming similar or different piezoelectric thin films adjacent to an additional electrode.

In all the foregoing embodiments, the method may also comprise forming the piezoelectric thin film element so that it has one or more end surfaces which are beveled or filleted.

The method may, in particular, comprise forming the piezoelectric thin film element to have one, two, three or four end surfaces which are beveled and contact the substrate at one or more angles between 45° and 75°, for example, 70°, 65°, 60°, 55° or 50°. In particular, the method may provide (for example, by etching) that the piezoelectric thin film element has at least two beveled surfaces which contact the diaphragm at an angle of between 45° and 75°, for example, 70°, 65°, 60°, 55° or 50° to the major plane of the substrate.

In a third aspect, the present invention provides a piezoelectric thin film element comprising a first electrode, a second electrode and one or more piezoelectric thin films there between, characterised in that the thin film element has a piezoelectric thin film adjacent to the first electrode which includes a plurality of thin film layers which, together, define a gradient in elastic modulus and/or piezoelectric strain constant across at least a part of the thin film, in its thickness direction. Said plurality of thin film layers is characterised in that it includes thin film layers which are doped by an acceptor dopant and define a gradient in acceptor dopant concentration in the thickness direction of the film, and thin film layers which are doped by a donor dopant and define a gradient in dopant concentration in the thickness direction of the film. The piezoelectric film may also comprise undoped piezoelectric film layers.

In this aspect, the present invention may provide an electrode arrangement in which a single piezoelectric thin film is interposed between the first and second electrode with or without one or more additional electrodes (and piezoelectric thin films). In the case of a plurality of thin films and additional electrodes, the electric field strength experienced by each piezoelectric thin film will be the same.

In a fourth aspect, the present invention provides an actuator for a printhead, which actuator comprises a piezoelectric element according to the first aspect.

In a fifth aspect, the present invention provides a printhead, comprising the actuator according to the fourth aspect.

In a sixth aspect, the present invention provides an inkjet printer, comprising the printhead according to the fifth aspect.

Embodiments of the actuator, printhead and inkjet printer will be apparent from the first and second aspects.

The present inventors have surprisingly found that the above-mentioned combinations minimise interface stress in piezoelectric thin film elements to a far greater extent than any one component of the combination.

They have, in particular, found that electrode arrangements, piezoelectric displacement constant and elastic modulus in piezoelectric thin films are to be engineered so as to work together to minimise interface stress and, consequently, to improve reliability, of piezoelectric thin film elements but maintain or improve piezoelectric performance as compared to prior art piezoelectric elements.

The present invention is now described in more detail with reference to the following non-limiting embodiments and the accompanying drawings in which:

FIGS. 1 to 5 show section views of piezoelectric thin film elements (and diaphragm) particularly pointing out electrode arrangements according to the present invention;

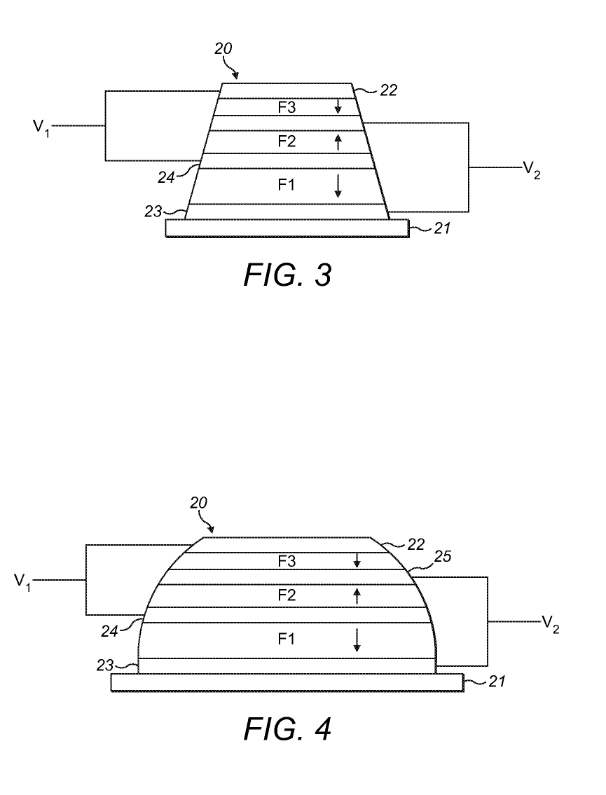

FIGS. 6 to 9 are graphs showing lateral stress in the bottom electrode and across the piezoelectric elements of FIGS. 1 and 3;

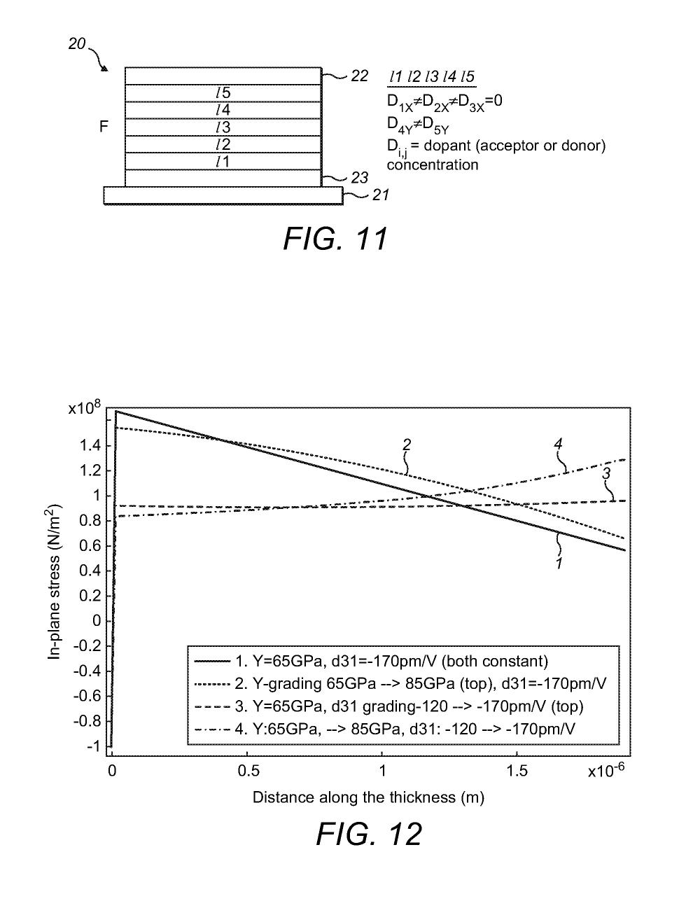

FIGS. 10 and 11 show section views of piezoelectric thin film elements (and diaphragm) according to several embodiments of the present invention;

FIGS. 12 to 14 are graphs showing lateral stresses in the piezoelectric thin film element according to several embodiments of the present invention;

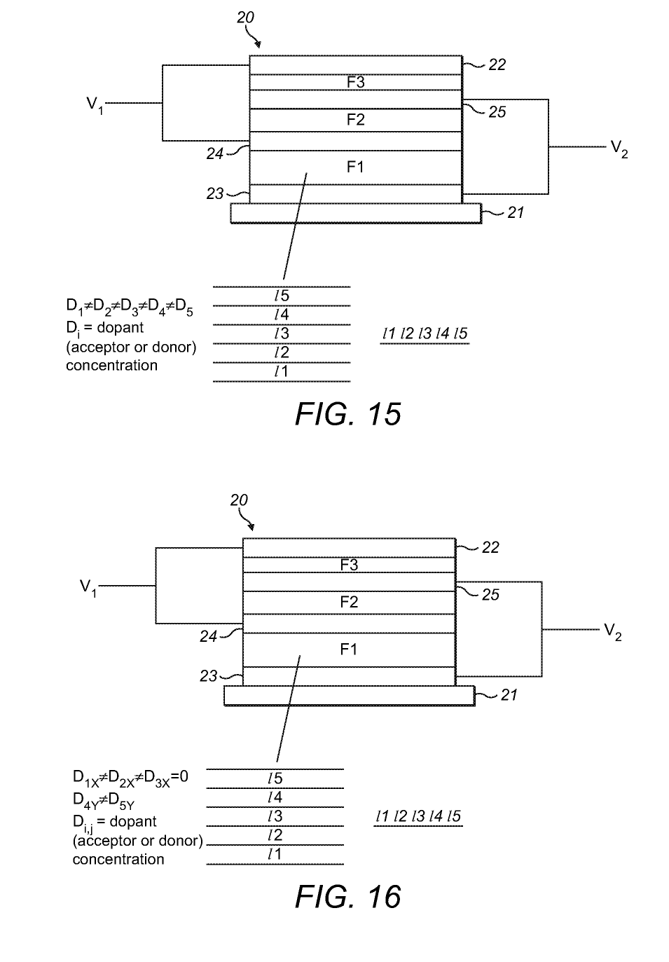

FIGS. 15 and 16 show section views of piezoelectric thin film elements (and diaphragm) according to several other embodiments of the present invention;

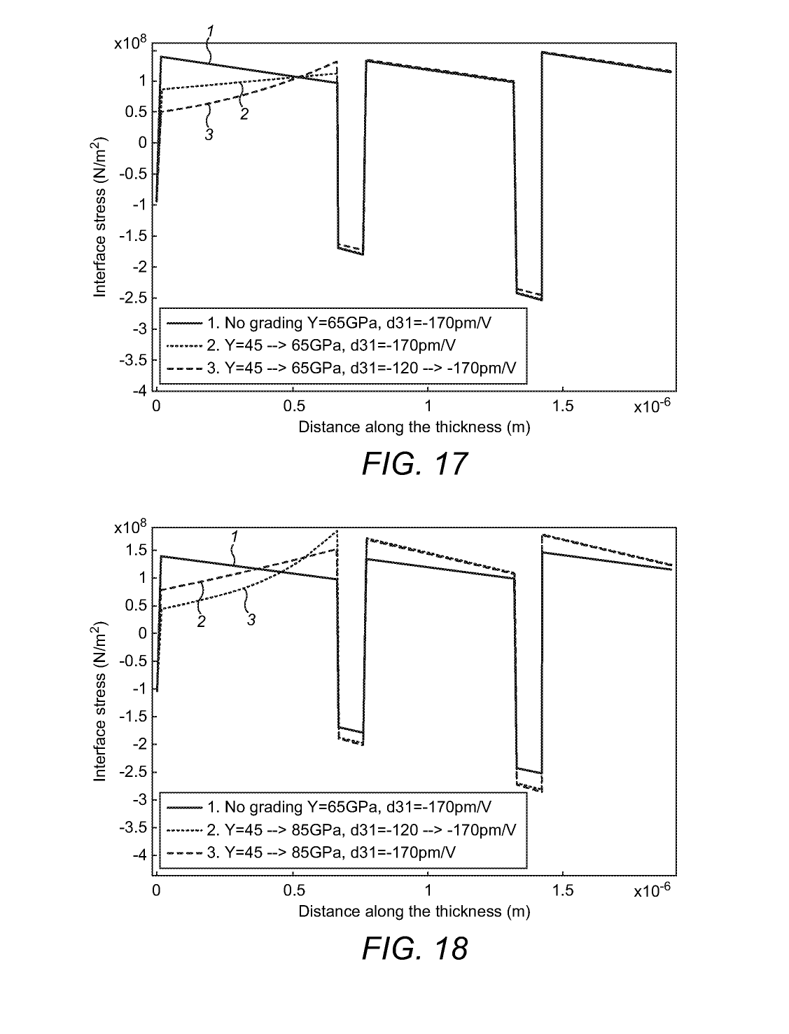

FIGS. 17 and 18 are graphs showing lateral stresses in the piezoelectric thin film element according to several embodiments of the present invention; and

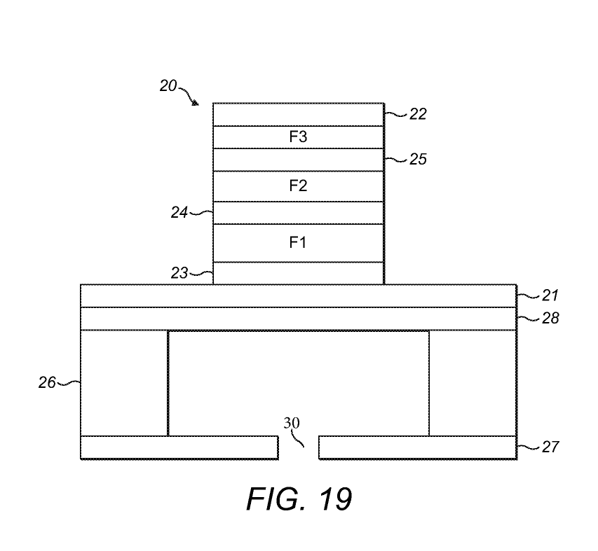

FIG. 19 shows a section view of part of a piezoelectric actuator according to one embodiment of the present invention.

FIG. 1 shows a section view of a piezoelectric thin film element 20 (and diaphragm 21) in which the electrode arrangement comprises a plurality of piezoelectric thin films F1 to F3 alternately arranged between a top electrode 22, a bottom electrode 23 and intermediate electrodes 24 and 25.

The films Fi may each comprise a plurality (n) of identical or different thin film layers Ir1 , Ir2 and Ir3 etc. but, as mentioned above, these need not be discrete.

The thickness of the piezoelectric thin film adjacent the bottom electrode F1 is greater than the thickness of the adjacent piezoelectric thin film F2—and thickness of the piezoelectric thin film F2 is greater than the thickness of the adjacent piezoelectric thin film F3.

The thickness of the piezoelectric thin film F2 may, however, be similar to or less than the thickness of the adjacent piezoelectric thin film F3.

In any case, the top electrode 22 is connected with an intermediate electrode 24 separating adjacent piezoelectric thin films F2 and F1 to a voltage source V₁. The bottom electrode 23 is connected with an intermediate electrode 25 separating adjacent piezoelectric thin films F2 and F3 to another voltage source V₂.

The electric field strength experienced by F1 is lower than the electric field strength experienced by F2 and F3 when the piezoelectric element is driven at voltages V₁ and V₂, provided that V₂<V₁; V₂ may be 0.

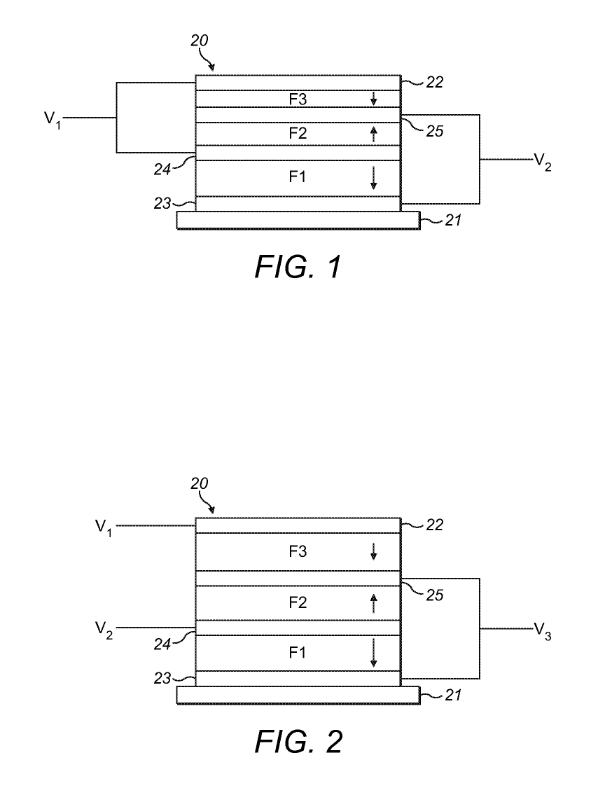

FIG. 2 shows a section view of a piezoelectric thin film element 20 (and diaphragm 21) of similar arrangement except that the thickness of each piezoelectric thin film Fi is similar.

The top electrode 22 and the intermediate electrode 24 separating adjacent piezoelectric thin films F2 and F1 are connected to separate voltage sources V₁ and V₂. The bottom electrode 23 and the intermediate electrode 25, separating adjacent piezoelectric thin films F2 and F3, are connected to another voltage source V₃.

The piezoelectric thin film F1 experiences an electric field strength which is lower than the electric field strength experienced by piezoelectric thin films F2 and F3 when the piezoelectric element is driven at predetermined voltages V₁ to V₃, provided that V₃<V₂<V₁.

If the bottom electrode 23 and the additional electrode 25 are separately connected to different voltages V₃ and V₄, the electric field strength experienced by the piezoelectric thin film adjacent the bottom electrode F1 is lower than the electric field strength experienced by the adjacent piezoelectric thin film F2 when the piezoelectric element is driven at predetermined voltages (V₁ to V₄) so that (V₂−V₃)<(V₂−V₄).

FIG. 3 shows a section view of a piezoelectric thin film element 20 (and diaphragm 21) similar to that shown in FIG. 1 except that the piezoelectric thin film element has end surfaces which are beveled. The end surfaces contact the diaphragm 21 at angle of 45° C. to the plane of the substrate (underlying the diaphragm; not shown).

FIG. 4 also shows a section view of a piezoelectric element 20 (and diaphragm 21) similar to that shown in FIG. 1 except that the piezoelectric thin film element has filleted end surfaces.

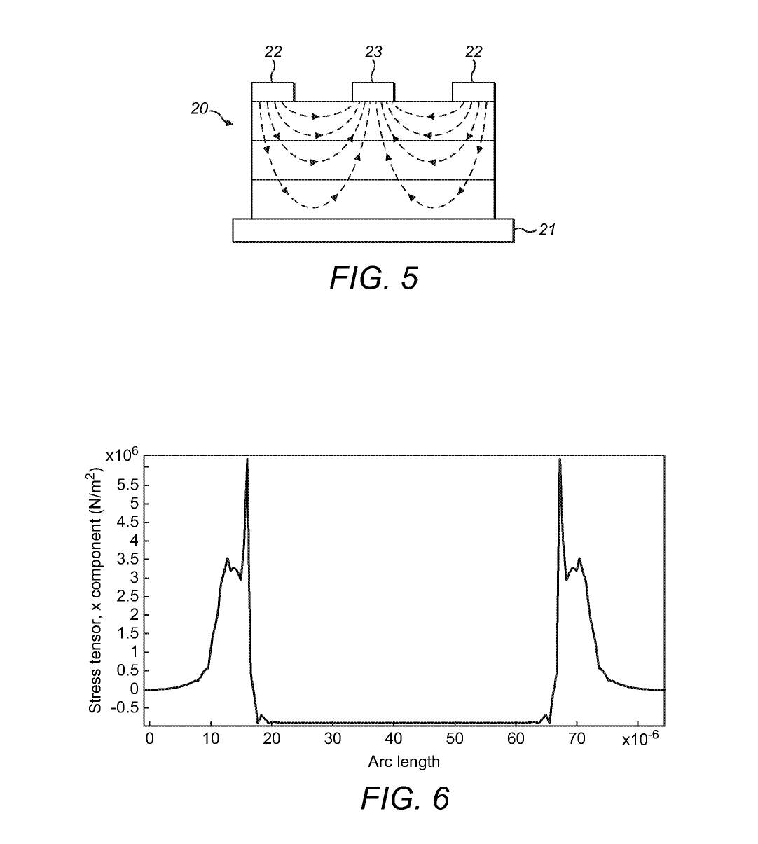

FIG. 5 shows a section view of a piezoelectric thin film element 20 (and diaphragm 21) comprising piezoelectric thin films F1 to F3 of similar thickness which are not separated by intermediate electrodes. Instead two interdigitated electrodes 22 and 23 are formed on the upper surface of piezoelectric thin film F3.

The interdigitated electrodes 22 and 23 are connected to different voltage sources V₁ and V₂ (not shown).

This electrode configuration provides that the electric field strength experienced by the piezoelectric thin film F1 is lower than the electric field strength experienced by the piezoelectric thin film F2 when the piezoelectric element is driven at a predetermined voltage or by predetermined voltages (V₁ and V₂).

A model study based on finite element analysis (using the commercially available software COMSOL v4.4/5.0) was used to calculate piezoelectric displacements and lateral stresses for a piezoelectric element having a single piezoelectric thin film and for the piezoelectric elements of FIGS. 1 and 2.

The study assumes PZT thin films provided on a platinum electrode, an alumina adhesive layer, a silica-silicon nitride diaphragm 21, and a silicon substrate (within conventional parameters and voltages).

The thickness of the single piezoelectric thin film was set at 1.8 μm. The thicknesses of the piezoelectric thin films F1 to F3 was set to vary in accordance with one or other electrode arrangement within a total thickness of 1.8 μm. The thickness of the platinum electrodes was set at 200 nm and the thickness of the bilayer diaphragm was set at 1.4 μm (0.7 μm for each layer).

FIG. 6 shows a graph which particularly points out the lateral stress produced in the diaphragm 21 at point (10 nm) below its upper surface by the piezoelectric element shown in FIG. 1 when it is driven; the thicknesses of the piezoelectric thin film layers F1 to F3 are respectively 0.7 μm, 0.6 μm, and 0.5 μm.

The peak interface stress of about 620 MPa compares well with that found for the piezoelectric thin film element having the single film F with thickness equal to the sum of the thicknesses of the Fi piezoelectric thin films, driven at a voltage which is equal to three times the voltage applied to each of the Fi piezoelectric thin films (about 640 MPa).

The peak interface stress is, however, similar to that found for the piezoelectric thin film element of FIG. 1 when the piezoelectric thin films F1 to F3 have the same thicknesses (0.6 μm) and are driven at the same voltage.

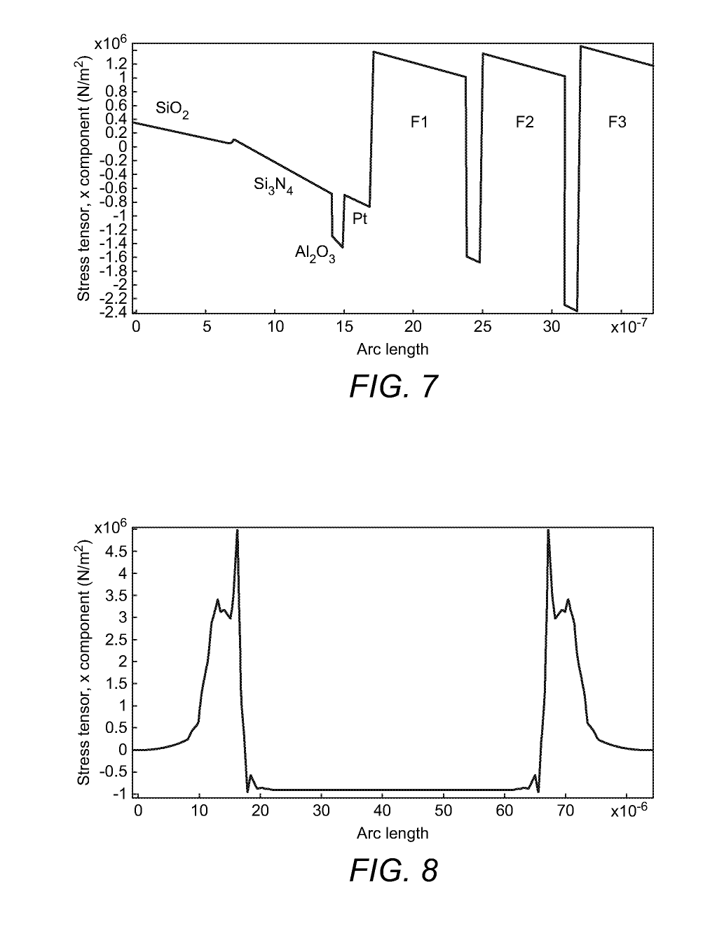

FIG. 7 shows a graph which particularly points out the lateral stress at the centre of the piezoelectric element shown in FIG. 1 plotted against the distance from the bottom surface of the diaphragm 21 in the thickness direction of the element when it is driven.

The lateral stress in the thin film contacting the bottom electrode F1 is about 140 MPa—and compares well with that found for the piezoelectric thin film element having the single film (about 170 MPa).

It also compares well with that found for the piezoelectric thin film element of FIG. 1 when the piezoelectric thin films F1 to F3 have the same thicknesses (0.6 μm; 160 MPa).

FIG. 8 shows a graph similar to that of FIG. 6, but related to the piezoelectric thin film element of FIG. 3 when the thicknesses of the piezoelectric thin film layers F1 to F3 are respectively 0.7 μm, 0.6 μm, and 0.5 μm.

The peak interface stress is about 500 MPa—which compares well with that for a piezoelectric element having a single film and similar end surfaces (about 530 MPa).

The peak interface stress is, however, similar to that found for the piezoelectric thin film element of FIG. 1 when the piezoelectric thin films F1 to F3 have the same thicknesses (0.6 μm).

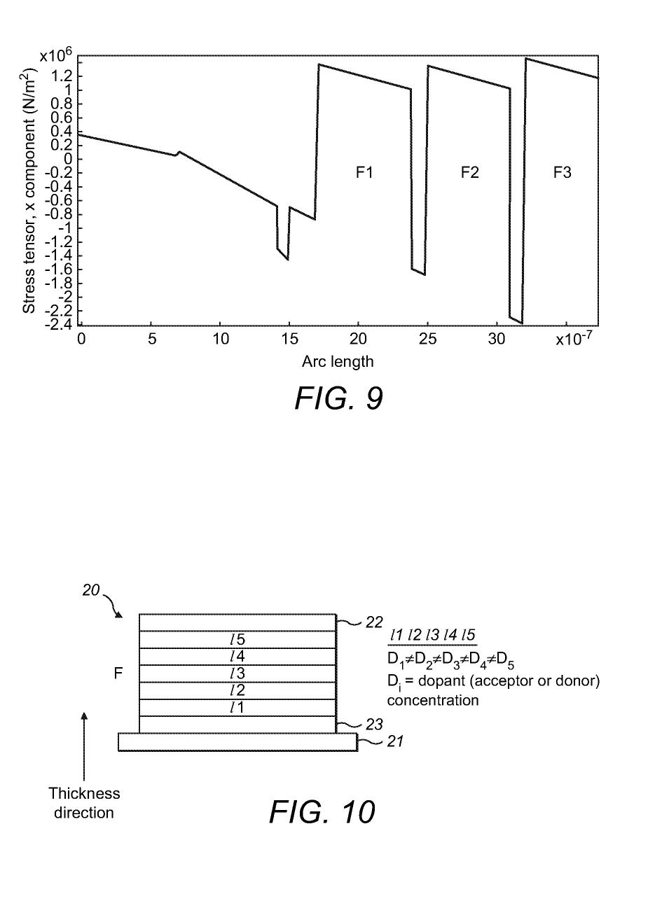

FIG. 9 shows a graph similar to that shown in FIG. 7. The lateral stress at the centre of the piezoelectric element shown in FIG. 3 is about 140 MPa—which compares well with that obtained for a piezoelectric element having a similar film and similar end surfaces (about 170 MPa).

It also compares well with the lateral stress found for the piezoelectric thin film element of FIG. 3 when the piezoelectric thin films F1 to F3 have the same thicknesses (0.6 μm; 170 MPa).

These and further results relating to the electrode arrangement shown in FIG. 1 are collected together in Table 1. The Table shows that peak interface stress is not particularly sensitive to film thicknesses but depends more upon end surfaces. It appears highest for those piezoelectric elements having vertical end surfaces and lower for piezoelectric elements having beveled or filleted end surfaces.

TABLE 1

| | | Peak | |
|---|---|---|---|
| | | Interface | Centre |
| | Number of piezoelectric thin | Stress/ | Stress/ |
| Edge | films and related thickness | MPa | MPa |
| Vertical | single film 1.8 μm | 640 | 170 |
| | 3 films t₁ = t₂ = t₃ = 0.6 μm | 620 | 160 |
| | 3 films | 620 | 140 |
| | t₁ = 0.7 μm, t₂ = 0.6 μm, t₃ = 0.5 μm | | |
| Bevelled | single film 1.8 μm | 520 | 170 |
| | 3 films t₁ = t₂ = t₃ = 0.6 μm | 500 | 165 |
| | 3 films | 500 | 140 |
| | t₁ = 0.7 μm, t₂ = 0.6 μm, t₃ = 0.5 μm | | |
| Filleted | single film 1.8 μm | 620 | 170 |
| | 3 films t₁ = t₂ = t₃ = 0.6 μm | 600 | 170 |
| | 3 films | 590 | 135 |
| | t₁ = 0.7 μm, t₂ = 0.6 μm, t₃ = 0.5 μm | | |

The lateral stress at centre (viz. in most of the area of the element) depends on film thickness and not on end surfaces. It is about the same in piezoelectric thin film elements having a single film and the piezoelectric thin film elements having piezoelectric thin films of similar thicknesses—but is significantly lower for piezoelectric thin film elements having piezoelectric thin films of different thicknesses.

The model shows, therefore, that lateral stress in piezoelectric thin film elements can be managed—by engineering the electric field strength through different thicknesses of the piezoelectric thin films.

FIG. 10 shows a section view of a piezoelectric thin film element according to one embodiment of the present invention. The piezoelectric thin film element 20 (and diaphragm, 21) comprises a single film which is interposed between a top electrode 22 and a bottom electrode 23.

The piezoelectric thin film comprises a plurality of piezoelectric thin film layers, for example, Ir1 to Ir5. These layers are shown as discrete layers of defined thickness and may be obtained, for example, by a sol-gel method.

However, as mentioned above, the layers need not have a defined thickness at all but simply be put down in the piezoelectric thin film by adaptation of the film forming method to provide a different material or a different processing condition at a particular time in the process.

The piezoelectric thin film layers Ir1 to Ir5 are singly doped by an acceptor dopant (or a donor dopant) at different dopant concentrations (Di). The dopant concentration is such that it gradually changes across the piezoelectric film thickness.

The thin film comprises a piezoelectric thin film layer Ir1, near to the bottom electrode 23 which has lower displacement performance compared to the layers further from the bottom electrode, so that the stress at the interface between the bottom electrode and the adjacent piezoelectric film layer is reduced. The displacement performance increases in the thickness direction either continuously or reaching a plateau.

FIG. 11 shows a section view of a piezoelectric thin film element according to another embodiment of the present invention. The piezoelectric thin film element 20 (and diaphragm 21) is similar to that shown in FIG. 10.

However, the piezoelectric thin film layer Ir3 is undoped, the piezoelectric thin film layers Ir1 and Ir2 are singly doped by a donor dopant and the piezoelectric thin film layers Ir4 and Ir5 are singly doped by an acceptor dopant.

The thin film comprises a piezoelectric thin film layer Ir1 near to the bottom electrode 23 which has lower displacement performance compared to the layers further from the bottom electrode, so that the stress at the interface between the bottom electrode and the adjacent piezoelectric film layer is reduced. The displacement performance increases in the thickness direction either continuously or reaching a plateau. A model study based on finite element analysis (using the commercially available software COMSOL v4.4/5.0) was used to calculate piezoelectric displacements and lateral stresses for piezoelectric elements similar to those shown in FIGS. 10 to 12.

The study assumes the same parameters as those mentioned in relation to FIGS. 5 to 7 but substitutes parameters for singly doped PZT and different processing condition or different composition of PZT which continuously vary (from 10 nm) in the thickness direction of the thin film.

FIG. 12 shows a graph similar to that shown in FIG. 7. The curves 1 to 4 show the lateral stress in the piezoelectric thin film and how it changes when the Young's modulus and/or the piezoelectric constant d₃₁ is made to change from the bottom electrode to the top electrode by gradually changing the acceptor dopant concentration.

Curve 1 shows a stress profile for a piezoelectric thin film in which the Young's modulus and the piezoelectric constant d₃₁ are the same for every layer of the thin film at respectively 65 GPa and −170 pm/V. As may be seen, the interface stress in the thin film is about 165 MPa.

Curve 2 shows a stress profile for a piezoelectric thin film in which the Young's modulus changes from 65 GPa in a thin film layer near to the bottom electrode (10 nm from the start of the film) to 85 GPa in a thin film layer near to the top electrode and the piezoelectric constant d₃₁ is the same (at −170 pm/V) for every layer of the thin film. As may be seen, the interface stress is slightly lower that that found from Curve 1—at about 155 MPa.

Curve 3 shows a stress profile for a piezoelectric thin film in which the piezoelectric constant d₃₁ changes from −120 pm/V in the thin film layer near to the bottom electrode to −170 pm/V in the thin film layer near to the top electrode and the Young's modulus is the same (at 65 GPa) for every layer of thin film layer. As may be seen, the interface stress is significantly lower than that found from Curve 1 and Curve 2—at about 90 MPa.

Curve 4 shows a stress profile for a piezoelectric thin film in which the Young's modulus and the piezoelectric constant d₃₁ changes from respectively 65 GPa and −120 pm/V in the thin film layer near to the bottom electrode to respectively 85 GPa and −170 pm/V in the thin film layer near to the top electrode. As may be seen, the interface stress is lower than that found from Curve 3 at about 85 MPa.

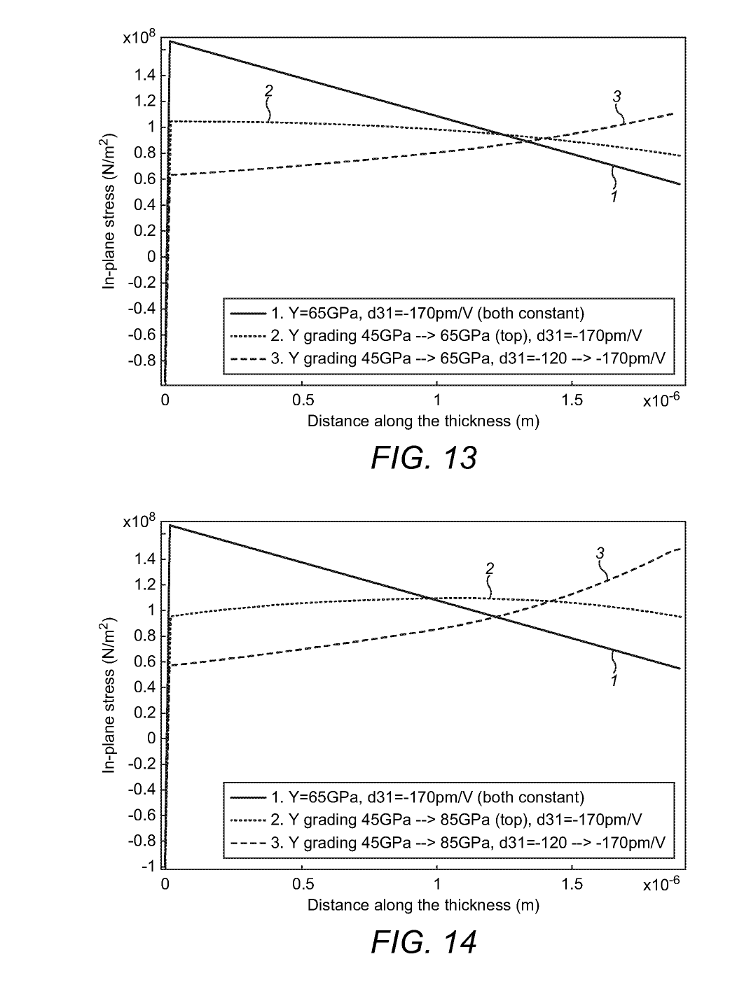

FIG. 13 shows a graph similar to that shown in FIG. 7. The Curves 1 to 3 show the lateral stress in the piezoelectric thin film and how it changes when the Young's modulus and/or the piezoelectric constant d₃₁ is made to change across the thin film by gradually changing the donor dopant concentration and/or the processing condition inside the piezoelectric thin film from the bottom electrode to the top electrode.

Curve 1 shows a stress profile for a piezoelectric thin film in which both the Young's modulus and the piezoelectric constant d₃₁ are the same for every layer of the thin film at respectively 65 GPa and −170 pm/V. As may be seen, the interface stress in the thin film is about 165 MPa.

Curve 2 shows a stress profile for a piezoelectric thin film in which the Young's modulus changes from 45 GPa in the thin film layer near to the bottom electrode (10 nm from the surface) to 65 GPa in a thin film layer near to the top electrode and the piezoelectric constant is the same (at −170 pm/V) in every layer of the thin film. As may be seen, the interface stress is significantly lower than that found in Curve 1—at about 105 MPa.

Curve 3 shows a stress profile for a piezoelectric thin film in which the Young's modulus and the piezoelectric constant d₃₁ change from respectively 45 GPa and −120 pm/V in the thin film layer near to the bottom electrode to respectively 65 GPa and −170 pm/V in the thin film layer near to the top electrode. As may be seen, the interface stress is significantly lower compared to that found in Curves 1 and 2—at about 60 MPa.

FIG. 14 shows a graph similar to that shown in FIG. 7. The Curves 1 to 3 show the lateral stress in the piezoelectric thin film and how it changes when the Young's modulus and/or the piezoelectric constant d₃₁ are made to change across the thin film by gradually changing the donor dopant concentration, acceptor dopant concentration and/or the processing condition inside the piezoelectric thin film from the bottom electrode.

Curve 1 shows a stress profile for the piezoelectric thin film in which both the Young's modulus and the piezoelectric constant d₃₁ are the same for every layer of the thin film—at respectively 65 GPa and −170 pm/V. As may be seen, the interface stress in the thin film is about 165 MPa.

Curve 2 shows a stress profile for the piezoelectric thin film in which the Young's modulus changes from 45 GPa in the thin film layer near to the bottom electrode (10 nm from start) to 85 GPa in a thin film layer near the top electrode and the piezoelectric constant d₃₁ (at −170 pm/V) is the same for every thin film layer. As may be seen the interface stress is significantly lower than that found from Curve 1—at about 100 MPa.

Curve 3 shows a stress profile in which both the Young's modulus and the piezoelectric constant d₃₁ change respectively from 45 GPa and −120 pm/V in the thin film layer near to the bottom electrode to respectively 85 GPa and −170 pm/V in the thin film layer near to the top electrode. As may be seen the interface stress is significantly lower than that found from Curves 1 and 2—at below 60 MPa.

Table 2 shows how the performance (the displaced area) of the piezoelectric element changes as the Young's modulus and piezoelectric constant d₃₁ change in these studies.

The first four entries relate to the stress profiles shown by the curves in FIGS. 12 and 13. When the Young's modulus and the piezoelectric constant d₃₁ are constant across the thin film, the displaced area of the actuator is 7.34×10⁻¹² m² and the interface stress is 165 MPa.

When the Young's modulus changes by changing the concentration of acceptor dopant across the thin film, the performance of the element is better but there is only a marginal improvement in interface stress.

When the piezoelectric constant d₃₁ changes across the thin film, the interface stress is substantially lower but at the expense of performance.

TABLE 2

| | | Displaced | Interface |
|---|---|---|---|
| Y/GPa | d₃₁/pmV⁻¹ | area/10⁻¹² m² | stress/MPa |
| 65 (const) | −170 (const) | 7.34 | 165 |
| 65 → 85 | −170 | 8.02 | 155 |
| 65 (const) | −120 → −170 | 6.73 | 90 |
| 65 → 85 | −120 → −170 | 7.49 | 85 |
| 45 → 65 | −170 | 6.88 | 105 |
| 45 → 65 | −120 → −170 | 6.32 | 60 |
| 45 → 85 | −170 | 7.70 | <100 |
| 45 → 85 | −120 → −170 | 7.18 | <60 |

However, when the Young's modulus and the piezoelectric constant d₃₁ change across the thin film, the performance of the element is better and the interface stress is substantially lower.

On the other hand, when the Young's modulus changes by changing the concentration of donor dopant across the thin film, the interface stress is substantially lower but at the expense of performance.

When the Young's modulus and the piezoelectric constant d₃₁ change across the thin film, the interface stress is significantly lower and the performance of the element is lower.

However, when the Young's modulus changes by changing the concentration of an acceptor dopant and the concentration of a donor dopant, the interface stress is significantly lower and the performance of the element is substantially unaffected.

FIG. 15 shows a section view of a piezoelectric element according to an embodiment of the present invention in which a piezoelectric element 20 (and diaphragm, 21) similar to that shown in FIG. 1 has a thin film F1 adjacent to the bottom electrode 23 comprising piezoelectric thin film layers Ir1 to Ir5 which are singly doped by an acceptor or by a donor dopant.

The piezoelectric thin film layers Ir1 to Ir5 define an acceptor dopant concentration gradient or a donor dopant concentration gradient.

FIG. 16 shows a section view of a piezoelectric element according to still another embodiment of the present invention in which a piezoelectric element 20 (and diaphragm, 21) similar to that shown in FIG. 1 has the thin film F1 adjacent to the bottom electrode 23 comprising piezoelectric thin film layers Ir1 to Ir5 which adjacent piezoelectric film layers are singly doped with an acceptor or donor dopant and are separated by an undoped piezoelectric film layer (Ir3).

The piezoelectric thin film layer near to the bottom electrode Ir1 has a lower displacement performance than the adjacent piezoelectric thin film layer Ir2. And this latter piezoelectric thin film layer has displacement performance lower than that of the adjacent piezoelectric thin film layer Ir3 and so on.

A model study based on finite element analysis (using the commercially available software COMSOL v4.4/5.0) was used to calculate piezoelectric displacements and lateral stresses for piezoelectric elements similar to those shown in FIGS. 16 to 18.

The study assumes the same parameters as those mentioned in relation to FIGS. 5 to 7 and to FIGS. 10 to 11 and that the voltage applied to each thin film is equal to one third of the voltage applied to a piezoelectric thin film element with a single piezoelectric thin film of thickness equal to the sum of the thicknesses of F1 to F3 in order to obtain the desired displacement.

FIG. 17 shows a graph similar to that shown in FIG. 7. The curves show the lateral stress in a piezoelectric thin film element similar to that shown in FIG. 15 and how it changes when the Young's modulus and/or the piezoelectric constant d₃₁ of the thin film near to the bottom electrode is changed by gradually changing donor dopant concentration as described above.

Curve 1 shows a stress profile in the piezoelectric thin film element when the Young's modulus and the piezoelectric constant d₃₁ are the same for every layer in the thin film adjacent to the bottom electrode (respectively, at 65 GPa and −170 pm/V). As may be seen (left hand side), the interface stress is about 140 MPa.

The reduction in stress as compared to the piezoelectric thin film element comprising a single thin film is due to the lower electric field strength experienced by the thin film adjacent the bottom electrode.

Curve 2 shows a stress profile in the piezoelectric thin film element when the Young's modulus changes from 45 GPa to 65 GPa and the piezoelectric constant d₃₁ is the same for every layer in the thin film adjacent to the bottom electrode. As may be seen, the interface stress is substantially lower than that found in Curve 1—at about 90 MPa.

The displacement area for the piezoelectric thin film element is similar to that for the piezoelectric element comprising the single thin film—at 6.07×10⁻¹² m². This slightly lower value is due to the additional electrode layers present in this actuator.

Curve 3 shows a stress profile in the piezoelectric thin film element when the Young's modulus and the piezoelectric constant d₃₁ change from respectively 45 GPa and −120 pm/V to respectively 65 GPa and −170 pm/V in the thin film layer adjacent to the bottom electrode. As may be seen, the interface stress is substantially lower at about 50 MPa.

The displacement area for the piezoelectric actuator is similar to that for the piezoelectric element comprising the single thin film—at 6.73×10⁻¹² m².

FIG. 18 shows a graph similar to that shown in FIG. 7. The curves show the lateral stress in a piezoelectric thin film element similar to that shown in FIG. 16 and how it changes when the Young's modulus and/or the piezoelectric constant d₃₁ of the thin film near to the bottom electrode are changed by gradually changing donor dopant concentration and acceptor dopant concentration as described above. As may be seen, the interface stress is about 50 MPa.

The displacement area for the piezoelectric actuator is slightly higher than that for the piezoelectric element comprising the single thin film—at 7.79×10⁻¹² m².

FIG. 19 shows a section view of part of an inkjet printhead according to one embodiment of the present invention. The piezoelectric thin film element is similar to that shown in FIG. 16 (piezoelectric thin film layers not shown) and is provided to a diaphragm 21 comprising a bilayer on top of a pressure chamber 26, provided with a nozzle plate 27.

The pressure chamber 26 is formed in a silicon single crystal of thickness about 200 μm and the diaphragm comprises a thin film comprising a bilayer of silicon dioxide and silicon nitride.

A buffer layer of ultra-thin titanium film or chromium film (not shown) (about 10 nm thick) may be interposed between the first electrode 23 and F1 and or underneath the first electrode 23. Other components including buffer layers, adhesion layers, seed layers may also be present.

In use, predetermined drive voltages V₁ and V₂ are applied to the electrodes 22 to 25 by a signal from a control circuit (not shown). The voltages cause the piezoelectric thin film element 20 to deform so deflecting the diaphragm 21 into the pressure chamber 26 and changing its volume. A sufficient increase in pressure within the pressure chamber 26 causes ink droplets to be ejected from the nozzle 30.

It will be appreciated, therefore, that the present invention provides for piezoelectric actuators having good performance and excellent reliability.

The present invention also permits tuning of piezoelectric elements to a particular requirement for performance and/or reliability depending on a particular application of the element, for example, between sensing, actuating and energy harvesting.

The present invention has been described in detail with reference to certain embodiments which are illustrated by the drawings. However, it will be understood that other embodiments not described in detail or illustrated by the drawings are also included within the scope of the present invention.

1. A piezoelectric thin film element comprising a first electrode, a second electrode and one or more piezoelectric thin films characterised in that the thin film element has at least two of:
a piezoelectric thin film adjacent to the first electrode in which a layer of the piezoelectric thin film near to the first electrode has a piezoelectric displacement constant which is lower than that of a layer of the piezoelectric thin film further from the first electrode;
a piezoelectric thin film adjacent to the first electrode in which a layer of the piezoelectric thin film near to the first electrode has an elastic modulus which is lower than that of a layer of the piezoelectric thin film further from the first electrode; and
an electrode arrangement in which electrodes are arranged with the one or more piezoelectric thin films so that an electric field applied to a piezoelectric thin film or a portion of a piezoelectric thin film adjacent to the first electrode is lower than an electric field applied to a piezoelectric thin film or a portion of a piezoelectric thin film further from the first electrode when the piezoelectric thin film element is actuated.

2. A piezoelectric thin film element according to claim 1, wherein the element comprises said electrode arrangement and a piezoelectric thin film adjacent to the first electrode in which a layer of the piezoelectric thin film near to the first electrode has a piezoelectric displacement constant and/or an elastic modulus which are lower than those of a layer of the piezoelectric thin film further from the first electrode.

3. A piezoelectric thin film element according to claim 1, wherein the electrode arrangement comprises one or more additional electrodes.

4. (canceled)

5. (canceled)

6. A piezoelectric thin film element according to claim 2, wherein the piezoelectric thin films have different thicknesses and the thickness of the piezoelectric thin film adjacent the first electrode is greater than that of a piezoelectric film adjacent a neighbouring electrode.

7. (canceled)

8. (canceled)

9. A piezoelectric thin film element according to claim 1, wherein the electrode arrangement comprises an interdigitated first electrode and the second electrode on a surface of a piezoelectric thin film.

10. A piezoelectric thin film element according to claim 1, wherein the piezoelectric thin film adjacent the first electrode includes a plurality of thin film layers which together define a gradient in piezoelectric displacement constant across at least a part of the thin film in its thickness direction.

11. A piezoelectric thin film element according to claim 1, wherein the piezoelectric thin film adjacent the first electrode includes a plurality of thin film layers which together define a gradient in elastic modulus across at least a part of the thin film in its thickness direction.

12. A piezoelectric thin film element according to claim 1, wherein the piezoelectric thin film adjacent the first electrode includes a plurality of thin film layers which together define a gradient in elastic modulus across at least a part of the thin film in its thickness direction and which are doped by a dopant.

13. A piezoelectric thin film element according to claim 1, wherein the piezoelectric thin film adjacent the first electrode includes a plurality of thin film layers which together define a gradient in elastic modulus across at least a part of the thin film in its thickness direction wherein the thin film layers are doped and define a gradient in at least one of the dopant concentration across the thin film in its thickness direction.

14. (canceled)

15. A piezoelectric thin film element according to claim 13, the piezoelectric thin film adjacent the first electrode includes a plurality of thin film layers which together define a gradient in elastic modulus across at least a part of the thin film in its thickness direction wherein the thin film layers are doped and define a gradient in at least one dopant concentration across the thin film in its thickness direction and in which the thin film layer near to the first electrode is undoped.

16. A piezoelectric thin film element according to claim 1, wherein the piezoelectric thin film element has an end surface which is beveled or filleted.

17. A method for manufacturing a piezoelectric thin film element having a first electrode, a second electrode and one or more piezoelectric thin films between the electrodes, characterised in that the method comprises at least two of:
forming a piezoelectric thin film adjacent to the first electrode so that a layer of the piezoelectric thin film near to the first electrode has a piezoelectric displacement constant which is lower than that of a layer of a piezoelectric thin film further from the first electrode;
forming a piezoelectric thin film adjacent to the first electrode so that a layer of the piezoelectric thin film near to the first electrode has an elastic modulus which is lower than that of a layer of the piezoelectric thin film further from the first electrode; and
arranging electrodes with the one or more piezoelectric thin films so that an electric field applied to a piezoelectric thin film or a portion of a piezoelectric thin film adjacent to the first electrode is lower than an electric field applied to a piezoelectric thin film or a portion of the piezoelectric thin film adjacent to the second electrode when the piezoelectric thin film element is driven by one or more predetermined voltages.

18. (canceled)

19. (canceled)

20. (canceled)

21. (canceled)

22. (canceled)

23. A method according to claim 17, comprising arranging the first and second electrodes with one or more additional electrodes and a plurality of piezoelectric thin films so that they interpose and alternate with the plurality of the piezoelectric thin films wherein the piezoelectric thin films have different thicknesses from one another, and the thickness of the piezoelectric thin film adjacent the first electrode is greater than that of a piezoelectric thin film adjacent a neighbouring electrode, with the electrodes so that the thin film adjacent the first electrode has thickness greater than the thin film adjacent a neighbouring electrode and the first and second electrodes are separately addressed with a respective additional electrode by two predetermined voltages.

24. (canceled)

25. (canceled)

26. (canceled)

27. A method according to claim 17, comprising forming a piezoelectric thin film adjacent to the first electrodes having a plurality of thin film layers which together define a gradient in piezoelectric displacement constant across at least a part of the thin film in its thickness direction.

28. A method according to claim 17, comprising forming a piezoelectric thin film adjacent to the first electrode having a plurality of thin film layers which together define a gradient in elastic modulus across at least a part of the thin film in its thickness direction.

29. A method according to claim 17, wherein the piezoelectric thin film adjacent to the first electrode has a plurality of thin film layers that are doped and that together define a gradient in elastic modulus across at least a part of the thin film in its thickness direction that are doped by at least a dopant.

30. A method according to claim 17, wherein the piezoelectric thin film adjacent to the first electrode has a plurality of thin film layers that together define a gradient in elastic modulus across at least a part of the thin film in its thickness direction that are doped and define a gradient in at least one dopant concentration across at least a part of the thin film in its thickness direction.

31. A method according to claim 17, wherein the piezoelectric thin film adjacent to the first electrode has a plurality of doped thin film layers that together define a gradient in elastic modulus across at least a part of the thin film in its thickness direction and wherein thin film layer near to the first electrode is undoped.

32. A method according to claim 17, comprising forming the piezoelectric thin film element so that it has an end surface which is beveled or filleted.

33. (canceled)

34. A printhead for an inkjet printer comprising a piezoelectric actuator comprising a piezoelectric thin film element comprising a first electrode, a second electrode and one or more piezoelectric thin films characterised in that the thin film element has at least two of:
a piezoelectric thin film adjacent to the first electrode in which a layer of the piezoelectric thin film near to the first electrode has a piezoelectric displacement constant which is lower than that of a layer of the piezoelectric thin film further from the first electrode;
a piezoelectric thin film adjacent to the first electrode in which a layer of the piezoelectric thin film near to the first electrode has an elastic modulus which is lower than that of a layer of the piezoelectric thin film further from the first electrode; and
an electrode arrangement in which electrodes are arranged with the one or more piezoelectric thin films so that an electric field applied to a piezoelectric thin film or a portion of a piezoelectric thin film adjacent to the first electrode is lower than an electric field applied to a piezoelectric thin film or a portion of a piezoelectric thin film further from the first electrode when the piezoelectric thin film element is actuated.

35. (canceled)

36. (canceled)
